(19) United States
(12) Patent Application Publication
(10) Pub. No.: US 2025/0208198 A1
(43) Pub. Date: Jun. 26, 2025

(54) ELECTRONIC COMPONENT INSPECTION DEVICE AND ELECTRONIC COMPONENT INSPECTION METHOD

(71) Applicant: CENTRUM TECHNOLOGY CORP., Taoyuan City (TW)

(72) Inventors: Tong-Yi CHUANG, Taoyuan City (TW); Hao-Wei HSU, Taoyuan City (TW)

(21) Appl. No.: 18/830,288

(22) Filed: Sep. 10, 2024

(30) Foreign Application Priority Data
Dec. 26, 2023 (TW) 112150838

(51) Int. Cl. G01R 31/28

(52) U.S. Cl. CPC G01R 31/2875; G01R 31/2887

(57) ABSTRACT

An electronic component inspection device and an electronic component inspection method are provided. The electronic component inspection device includes a carrier, a heating module, and an inspection module. The carrier carries the electronic component. The heating module includes a first heating source and a second heating source. The first heating source is placed on one side of the carrier and irradiates one surface of the electronic component. The second heating source is placed on the other side of the carrier and irradiates the other surface of the electronic component. The inspection module includes a moving mechanism and an inspection probe mounted on the moving mechanism. The moving mechanism is arranged corresponding to the carrier and drives the inspection probe to test the electronic component.

### BACKGROUND OF THE DISCLOSURE

### Technical Field

The present application relates to an inspection device for inspection electronic components, and more particularly, to an electronic component inspection device and an electronic component inspection method.

### Description of Related Art

Electronic components, such as printed circuit boards (PCBs), wafers, liquid crystal panels, IC substrates, and other products that require heated electrical inspection, typically have circuits and a plurality of circuit nodes disposed on the circuits. A plurality of electronic components are electrically connected to the plurality of circuit nodes, and the electronic components are controlled through the circuits, making the aforementioned electronic components widely used in various electronic products.

The circuit nodes of electronic components such as PCBs may have problems such as insufficient thickness of the metal layer or cracks or peeling of the metal layer, or other factors, resulting in the circuit nodes being unable to conduct normally or having poor contact when heated. Therefore, manufacturers test the circuit nodes of the PCBs before shipment.

However, related-art circuit node inspection adopts ceramic contact to heat printed circuit boards, which causes only a portion of the PCB in contact with a ceramic heating structure to be heated, while the other portion not in contact with the ceramic heating structure is not heated, resulting in problems such as uneven heating of the PCB during the inspection process and inaccurate yield rates.

In view of this, the inventor of the present disclosure specifically focused on the aforementioned related-art technology and diligently engaged in research combined with the application of theoretical knowledge, striving to address the aforementioned issues, which became the objective of development

### SUMMARY OF THE DISCLOSURE

The present application provides an electronic component inspection device and an electronic component inspection method, which utilizes a heating module to heat the electronic component, so as to achieve the effect of uniform heating of the electronic component and improve the inspection accuracy and yield rate.

In the present disclosure, an electronic component inspection device and an electronic component inspection method are provided for inspection an electronic component. The electronic component inspection device includes: a carrier configured to carry the electronic component; a heating module including a first heating source and a second heating source, wherein the first heating source is disposed over the carrier and configured to irradiate an upper surface of the electronic component, and the second heating source is disposed below the carrier and configured to irradiate a lower surface of the electronic component; and at least one inspection module including a moving mechanism and an inspection probe mounted on the moving mechanism, wherein the moving mechanism is disposed corresponding to the carrier and configured to drive the inspection probe to inspect the electronic component.

Based on the above, compared to related-art methods of using ceramic contact for heating electronic components, the electronic component inspection device of the present disclosure adopts a heating module to irradiate the electronic component in large area for heating. The first heating source is disposed over the carrier and may irradiate a large area of the upper surface of the electronic component, and the second heating source is disposed below the carrier and may irradiate a large area of the lower surface of the electronic component. The heating module enables uniform heating of the electronic component, thereby increasing the yield of inspection and achieving the effectiveness of uniformly heating the electronic component and enhancing both the accuracy and yield of inspections.

### BRIEF DESCRIPTION OF THE DRAWINGS

FIG. 1 is a process flow diagram illustrating steps of an electronic component inspection method according to the present application.

FIG. 2 is a schematic top view of an electronic component inspection device according to the present application.

FIG. 3 is another schematic top view of the electronic component inspection device according to the present application.

FIG. 4 is a schematic front view of the electronic component inspection device according to the present application.

FIG. 5 is a schematic view showing a translation movement of a carrier relative to a heating module according to the present application.

FIG. 6 is another schematic view showing the translation movement of the carrier relative to the heating module according to the present application.

FIG. 7 is yet another schematic view of the translation movement of the carrier relative to the heating module according to the present application.

FIG. 8 is still another schematic view of the translation movement of the carrier relative to the heating module according to the present application.

### DETAILED DESCRIPTION

The detailed description and the technical content of the present application are explained in conjunction with the drawings. However, the attached drawings are for illustrative purposes only and are not intended to limit the scope of the present application.

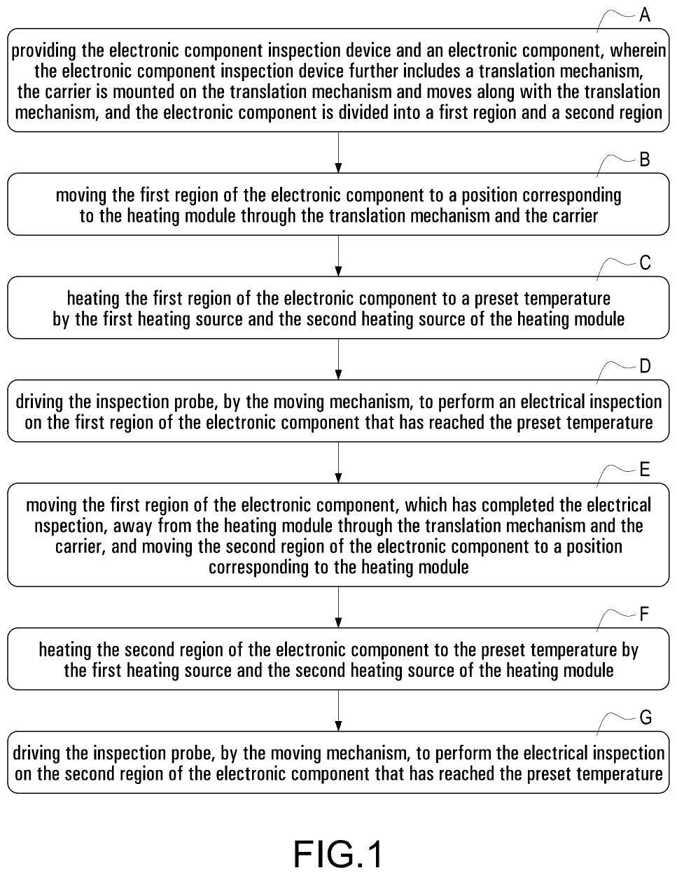

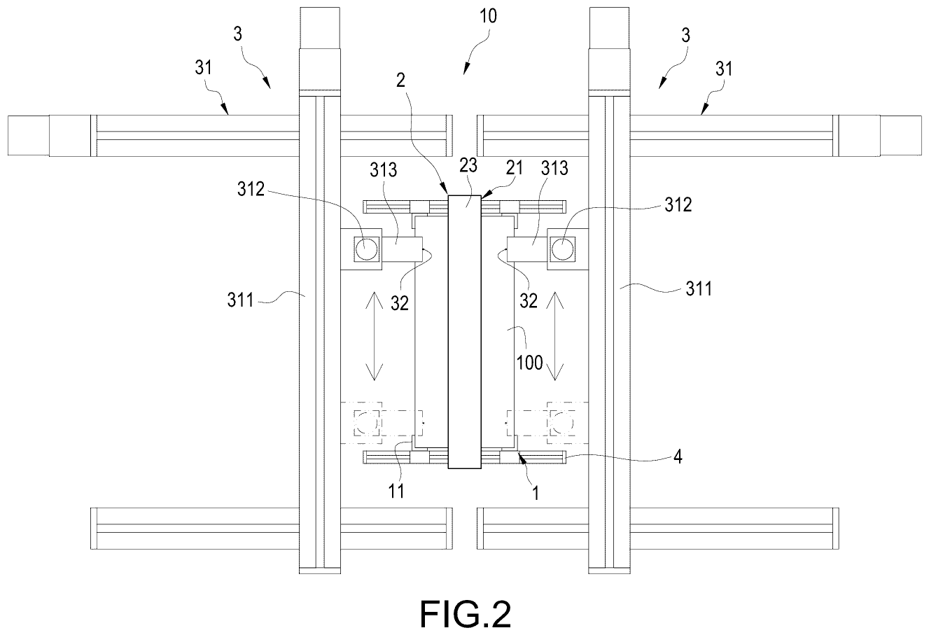

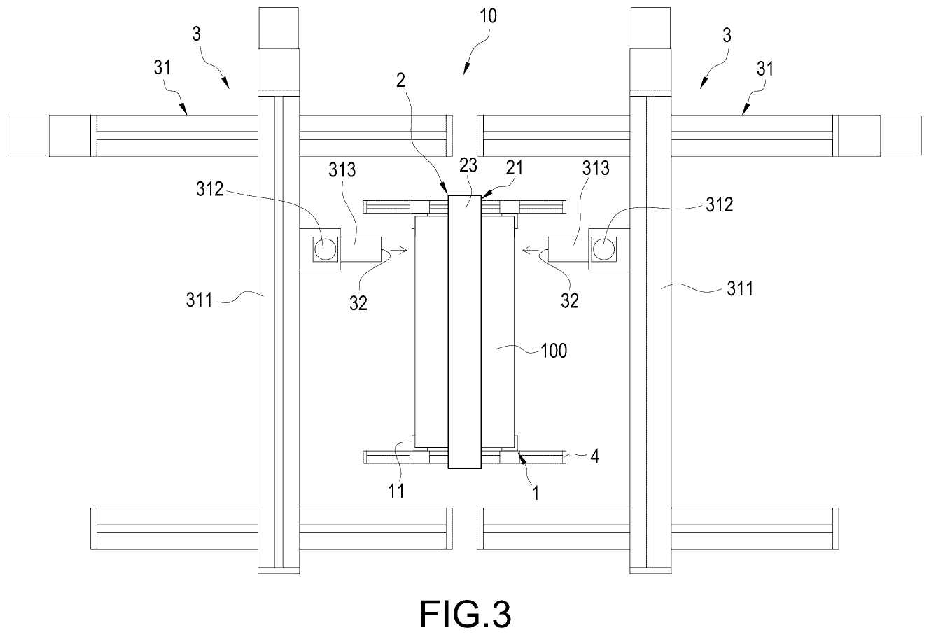

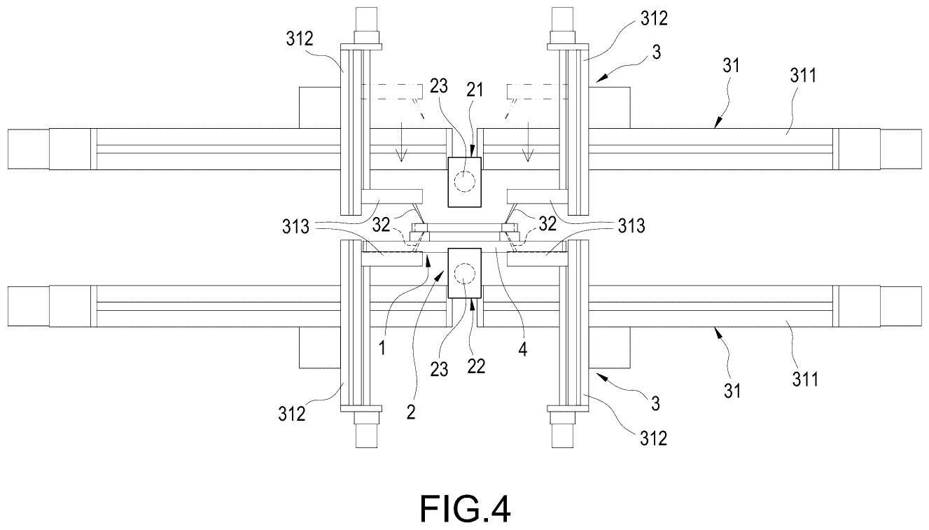

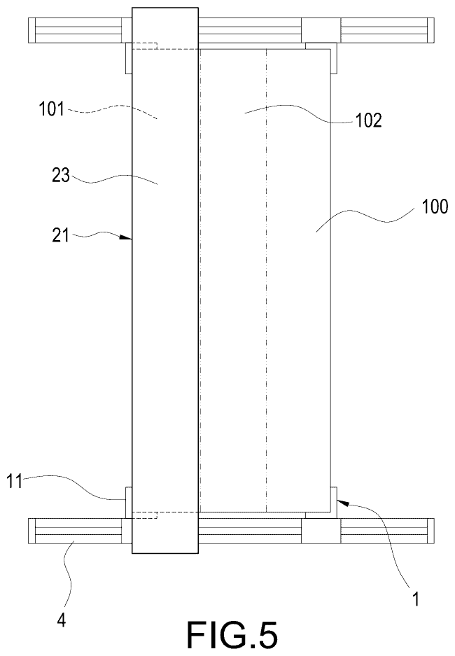

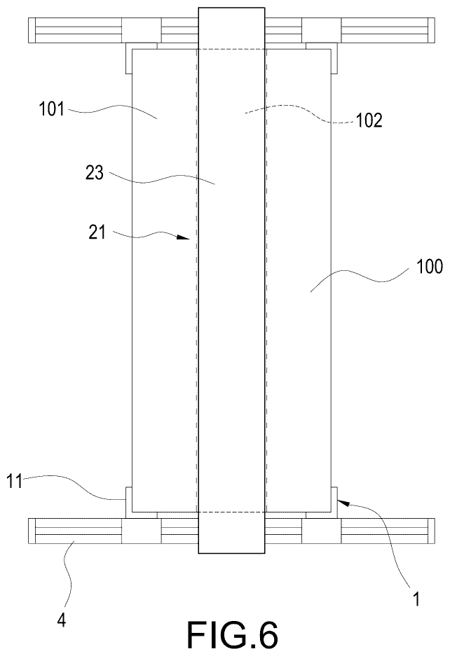

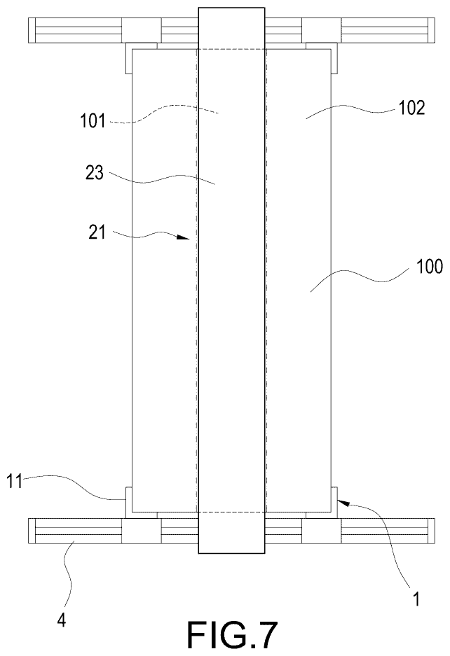

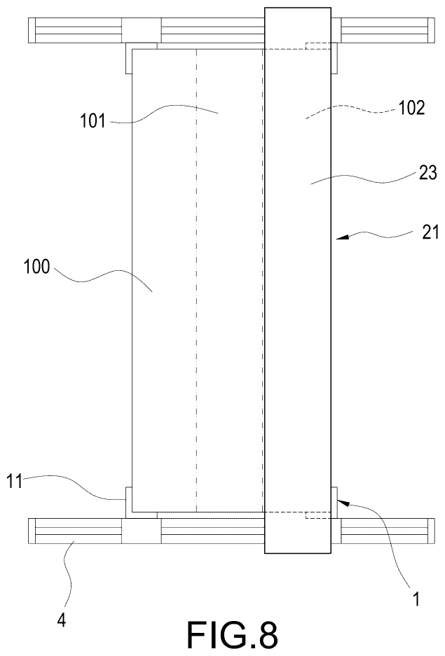

Please refer to FIGS. 1 to 8. The present application provides an electronic component inspection device and an electronic component inspection method for an electronic component 100. The electronic component inspection device 10 mainly includes a carrier 1, a heating module 2, and one or more inspection modules 3.

As shown in FIGS. 1 to 6, the carrier 1 is configured to carry the electronic component 100. The carrier 1 has a hollow region therein, and the two surfaces of the electronic component 100 opposite to each other are exposed from the hollow region.

As shown in FIGS. 1 to 6, the heating module 2 includes a first heating source 21 and a second heating source 22. The first heating source 21 is disposed on one side of the carrier 1 and configured to irradiate one surface of the electronic component 100, and the second heating source 22 is disposed on the other side of the carrier 1 and configured to irradiate the other surface of the electronic component 100. The first heating source 21 and the second heating source 22 are disposed opposite to each other.

In addition, the first heating source 21 and the second heating source 22 are a halogen heating lamp 23, respectively. In one embodiment, the halogen heating lamp 23 is a gold halogen heating lamp. The gold halogen heating lamp has the advantages of being able to instantly rise to a temperature higher than or equal to 500° C., high infrared radiation efficiency, high power, and fast heating speed. Its special gold outer layer coating may control the temperature to 1650 Kelvin (a unit of thermometric measurement), making it more eye-protective, not dazzling when viewed directly, with a main radiation wavelength between 0.8 and 1.4 microns (micrometers). It may also be adjusted through a controller, is economically priced, and has a long service life.

As shown in FIGS. 1 to 3, the inspection module 3 includes a moving mechanism 31 and an inspection probe 32 mounted on the moving mechanism 31. The moving mechanism 31 is disposed corresponding to the carrier 1 and configured to drive the inspection probe 32 to inspect the electronic component 100 for conditions such as whether the circuit nodes are conducting normally or have poor contact.

In more detail, the moving mechanism 31 includes a translation drive assembly 311, an elevation drive assembly 312 mounted on the translation drive assembly 311, and a fixed seat 313 mounted on the elevation drive assembly 312. The inspection probe 32 is fixed to the fixed seat 313. The fixed seat 313 lifts up and down relative to the electronic component 100 through the elevation drive assembly 312, and the elevation drive assembly 312 linearly moves left and right relative to the electronic component 100 through the translation drive assembly 311.

In this embodiment, the number of the inspection modules 3 is four, but the present application is not limited thereto. Two inspection modules 3 are disposed on left and right of one side of the carrier 1, and the other two inspection modules 3 are disposed on left and right of the other side of the carrier 1, so that the four inspection probes 32 may inspect left and right sides of the upper surface and left and right sides of the lower surface of the electronic component 100.

As shown in FIGS. 1 to 6, the electronic component inspection device 10 of the present disclosure further includes a translation mechanism 4. The carrier 1 is mounted on the translation mechanism 4 and may linearly move left and right along with the movement of the translation mechanism 4, relative to the first heating source 21 and the second heating source 22.

In addition, the translation drive assembly 311, the elevation drive assembly 312, and the translation mechanism 4 may be the components such as linear slides or motor-driven push rods, and are not limited to what is disclosed in the drawings of this embodiment.

As shown in FIGS. 1 to 6, in the operational state of the electronic component inspection device 10 of the present application, the heating module 2 is utilized to heat the electronic component 100. The first heating source 21 is disposed over the carrier 1 and is capable of irradiating a large area of the upper surface of the electronic component 100. The second heating source 22 is disposed below the carrier 1 and is capable of irradiating a large area of the lower surface of the electronic component 100.

In this way, compared to related-art methods of using ceramic contact to heat the electronic component, the electronic component inspection device 10 of the present disclosure adopts a heating module 2 to irradiate the electronic component 100 in large area for heating, which enables the electronic component 100 to be heated more uniformly, thereby increasing the yield of successful inspections and achieving the effectiveness of uniformly heating the electronic component 100 and enhancing both the accuracy and yield of inspections.

In addition, the first heating source 21 and the second heating source 22 are each a halogen heating lamp 23, so that the heating module 2 has the advantages of being able to instantly rise in temperature, fast heating speed, high infrared radiation efficiency, economical price, and long service life.

What is claimed is:

1. An electronic component inspection device, for inspection an electronic component, the electronic component inspection device comprising:
a carrier, configured to carry the electronic component;
a heating module, comprising a first heating source and a second heating source, wherein the first heating source is disposed on one side of the carrier and irradiates one surface of the electronic component, and the second heating source is disposed on another side of the carrier and irradiates another surface of the electronic component; and
at least one inspection module, comprising a moving mechanism and an inspection probe mounted on the moving mechanism, wherein the moving mechanism is disposed corresponding to the carrier and configured to drive the inspection probe to inspect the electronic component.

2. The electronic component inspection device according to claim 1, wherein the first heating source and the second heating source are a halogen heating lamp, respectively.

3. The electronic component inspection device according to claim 2, wherein the halogen heating lamp is a gold halogen heating lamp.

4. The electronic component inspection device according to claim 1, wherein the first heating source and the second heating source are disposed opposite to each other.

5. The electronic component inspection device according to claim 4, further comprising a translation mechanism, wherein the carrier is mounted on the translation mechanism and linearly moves relative to the first heating source and the second heating source along with the translation mechanism.

6. The electronic component inspection device according to claim 5, wherein the translation mechanism is a linear slide or a motor-driven push rod.

7. The electronic component inspection device according to claim 1, wherein the moving mechanism comprises a translation drive assembly, an elevation drive assembly mounted on the translation drive assembly, and a fixed seat mounted on the elevation drive assembly, the inspection probe is fixed to the fixed seat, and the translation drive assembly and the elevation drive assembly are a linear slide or a motor-driven push rod, respectively.

8. The electronic component inspection device according to claim 1, wherein a number of the inspection modules is four, two of the inspection modules are disposed on left and right of one side of the carrier, and other two of the inspection modules are disposed on left and right of another side of the carrier.

9. The electronic component inspection device according to claim 1, wherein the carrier has a hollow region defined therein, and two surfaces of the electronic component opposite to each other are exposed from the hollow region.

10. An electronic component inspection method, comprising:
A) providing the electronic component inspection device according to claim 1 and an electronic component, wherein the electronic component inspection device further comprises a translation mechanism, the carrier is mounted on the translation mechanism and moves along with the translation mechanism, and the electronic component is divided into a first region and a second region;
B) moving the first region of the electronic component to a position corresponding to the heating module through the translation mechanism and the carrier;
C) heating the first region of the electronic component to a preset temperature by the first heating source and the second heating source of the heating module;
D) driving the inspection probe, by the moving mechanism, to perform an electrical inspection on the first region of the electronic component that has reached the preset temperature;
E) moving the first region of the electronic component, which has completed the electrical inspection, away from the heating module through the translation mechanism and the carrier, and moving the second region of the electronic component to the position corresponding to the heating module;
F) heating the second region of the electronic component to the preset temperature by the first heating source and the second heating source of the heating module; and
G) driving the inspection probe, by the moving mechanism, to perform the electrical inspection on the second region of the electronic component that has reached the preset temperature.
